(19) United States
(12) Patent Application Publication
(10) Pub. No.: US 2017/0352753 A1
(43) Pub. Date: Dec. 7, 2017

(54) FIELD-EFFECT TRANSISTOR

(71) Applicant: SHARP KABUSHIKI KAISHA, Sakai City, Osaka (JP)

(72) Inventors: Tetsuzo NAGAHISA, Sakai City, Osaka (JP); Masayuki FUKUMI, Sakai City, Osaka (JP); Shinichi HANDA, Sakai City, Osaka (JP)

(73) Assignee: Sharp Kabushiki Kaisha, Sakai City, Osaka (JP)

(21) Appl. No.: 15/537,113

(22) PCT Filed: Aug. 24, 2015
(86) PCT No.: PCT/JP2015/073731

§ 371 Date: Jun. 16, 2017

(30) Foreign Application Priority Data
Dec. 18, 2014 (JP) 2014-255998

(51) Int. Cl. H01L 29/778; H01L 29/20; H01L 27/06; H01L 29/10; H01L 29/423; H01L 29/40

(52) U.S. Cl. CPC H01L 29/7787; H01L 29/42316; H01L 29/402; H01L 27/0605; H01L 29/1066; H01L 29/2003

(57) ABSTRACT

A field-effect transistor includes: a nitride semiconductor layer that includes a heterojunction; a source electrode and a drain electrode that are disposed on the nitride semiconductor layer at an interval; a first gate electrode that is located between the source electrode and the drain electrode and performs a normally-on operation; and a second gate electrode that is located between the first gate electrode and the source electrode and performs a normally-off operation. The first gate electrode is disposed to surround the drain electrode in plan view. The second gate electrode is disposed to surround the source electrode in plan view.

### TECHNICAL FIELD

The present invention relates to a field-effect transistor that has a heterostructure field-effect transistor (HFET) structure of a nitride semiconductor.

### BACKGROUND ART

A nitride semiconductor device that has the HFET structure is generally configured to perform a normally-on (an ON state at a gate voltage of 0 V) operation at a practical use level. However, to perform a safety operation so that no current flows even in a case in which control of the gate voltage becomes abnormal, a normally-off (an OFF state at a gate voltage of 0 V) operation is considerably desired.

A gate breakdown voltage is lowered to less than about 100 V even when the normally-off operation can be realized. In a power device field, while a gate breakdown voltage of more than about 100 V is necessary, it is considerably difficult to realize a high gate breakdown voltage.

Accordingly, it has been proposed that a method of realizing cascade connection using a nitride semiconductor element of the normally-on operation and a metal-oxide semiconductor (MOS) element of the normally-off operation. Also proposed has been that, as is used in semiconductor devices disclosed in Japanese Unexamined Patent Application Publication No. 2010-147387 (PTL 1), Japanese Unexamined Patent Application Publication No. 2014-123665 (PTL 2), and Japanese Unexamined Patent Application Publication No. 2013-106018 (PTL 3), a method of configuring cascode connection with a nitride semiconductor alone and a wiring using a gate of a normally-on operation of a high breakdown voltage and a gate of a normally-off operation of a low breakdown voltage to realize the normally-off operation.

For example, the semiconductor device disclosed in PTL 1 includes: a semiconductor region; a source electrode and a drain electrode which are formed on a main surface of the semiconductor region; a gate electrode of a low breakdown voltage that is formed with a p-type material film, which is installed on the main surface of the semiconductor region, interposed therebetween and that indicates normally-off characteristics and is disposed between the source electrode and the drain electrode; and a fourth electrode of a high breakdown voltage which is formed on the main surface of the semiconductor region and is disposed between the gate electrode and the drain electrode. When a voltage of 0 to about 10 V is applied to the fourth electrode using the source electrode as a standard, a high voltage of less than about 1000 V is applied between the drain electrode and the fourth electrode and no high voltage is applied to the gate electrode at the time of the normally-off operation.

The semiconductor device disclosed in PTL 2 includes: a first transistor which has a first gate electrode, a first source electrode, a first drain electrode, and a first nitride semiconductor laminate structure (including a first electron transit layer and a first electron supply layer); a p-type impurity diffusion prevention layer; and a second transistor which has a second gate electrode, a second source electrode, a second drain electrode which is a common electrode to the first source electrode, and a second nitride semiconductor laminate structure (including a second electron supply layer and a second electron transit layer containing p-type impurities) which is formed below the second gate electrode. The second nitride semiconductor laminate structure is formed on the first nitride semiconductor laminate structure with the p-type impurity diffusion prevention layer interposed therebetween. The first gate electrode and the second source electrode are electrically connected to each other and the first transistor and the second transistor are cascode-connected. In this way, the normally-off operation is realized while reducing ON resistance and enabling a high breakdown voltage.

The semiconductor device disclosed in PTL 3 includes a semiconductor laminate that includes a first heterojunction surface and a second heterojunction surface located above the first heterojunction surface; a drain electrode which is electrically connected to a first two-dimensional electron gas layer formed on the first heterojunction surface; a source electrode which is electrically connected to a second two-dimensional electron gas layer formed on the second heterojunction surface while electrically insulated from the first two-dimensional electron gas laver; a gate unit which is electrically connected to both of the first and second two-dimensional electron gas layers by a conductive electrode; and an auxiliary gate unit which is formed between the conductive electrode and the drain electrode on a main surface of the semiconductor laminate. The concentration of electrons of the first two-dimensional electron gas layer is denser than the concentration of the electrons of the second two-dimensional electron gas layer. In this way, a normally-off operation is performed, and a high breakdown voltage and low ON resistance are realized.

In the method of configuring the cascode connection using a nitride semiconductor element of the normally-on operation and a MOS structure element of the normally-off operation, a necessary chip area is immense, and thus there is a problem with a mounting surface. Further, there is also a problem that cost is high since two types of semiconductors are handled.

In the methods of configuring cascode connection with a nitride semiconductor alone and a wiring using a gate of a normally-on operation of a high breakdown voltage and a gate of a normally-off operation of a low breakdown voltage to realize the normally-off operation, as in the semiconductor devices disclosed in PTL 1 to PTL 3, two gates, that is, the gate performing the normally-off operation and the gate performing the normally-on operation, are used, and thus current leakage or breakdown occurs due to interaction between the two gates, and the source electrode and the drain electrode.

Accordingly, surrounding a drain electrode with a gate performing a normally-on operation and a gate performing a normally-off operation has been proposed.

For example, a III-nitride power semiconductor element disclosed in U.S. Pat. No. 8,174,051 (B2) (PTL 4) has a structure in which a drain electrode is surrounded by a Schottky electrode considered to be a gate performing a normally-on operation and the Schottky electrode (gate) is surrounded by a gate electrode (here, the width is narrower than the width of the Schottky electrode) considered to perform a normally-off operation.

### CITATION LIST

### Patent Literature

PTL 1: Japanese Unexamined Patent Application Publication No. 2010-147387

PTL 2: Japanese Unexamined Patent Application Publication No. 2014-123665

PTL 3: Japanese Unexamined Patent Application Publication No. 2013-106018

PTL 4: U.S. Pat. No. 8,174,051 (B2)

### SUMMARY OF INVENTION

### Technical Problem

However, the III-nitride power semiconductor element of the related art disclosed in PTL 4 has a structure in which the drain electrode and the source electrode with substantially the same length are arranged in parallel, the drain electrode is surrounded by the first gate electrode performing a normally-on operation, and the first gate electrode is surrounded by the second gate electrode performing a normally-off operation. Therefore, in the case of this structure, a distance between the gate and the source is considerably lengthened particularly at each of end portions, and thus there is a problem that a stability operation may not be performed due to influences of parasitic resistance and noise.

Accordingly, an object of the invention is to provide a field-effect transistor in which a stability operation can be performed, current leakage occurring in each of end portions is reduced, and breakdown rarely occurs in each of the end portions in a case in which cascode connection is configured with a nitride semiconductor alone and a wiring.

### Solution to Problem

To resolve the foregoing problem, a field-effect transistor according to the invention includes: a nitride semiconductor layer that includes a heterojunction; a source electrode and a drain electrode that are disposed on the nitride semiconductor layer at an interval; a first gate electrode that is located between the source electrode and the drain electrode and performs a normally-on operation; and a second gate electrode that is located between the first gate electrode and the source electrode and performs a normally-off operation. The first gate electrode is disposed to surround the drain electrode in plan view. The second gate electrode is disposed to surround the source electrode in plan view.

In the field-effect transistor according to an embodiment, the first gate electrode and the second gate electrode include a straight portion substantially straight in an edge of the first gate electrode and a straight portion substantially straight in an edge of the second gate electrode in plan view, and an end portion formed at a corner portion in which the edge of the first gate electrode is curved or bent and an end portion formed at a corner portion in which the edge of the second gate electrode is curved or bent in plan view. An interval between the first gate electrode and the drain electrode at the end portion is set to be equal to or greater than an interval between the first gate electrode and the drain electrode at the straight portion.

In the field-effect transistor according to an embodiment, the first gate electrode and the second gate electrode include a straight portion substantially straight in an edge of the first gate electrode and a straight portion substantially straight in an edge of the second gate electrode in plan view, and an end portion formed at a corner portion in which the edge of the first gate electrode is curved or bent and an end portion formed at a corner portion in which the edge of the second gate electrode is curved or bent in plan view. An interval between the second gate electrode and the source electrode at the end portion is set to be equal to or greater than an interval between the second gate electrode and the source electrode at the straight portion.

In the field-effect transistor according to an embodiment, the first gate electrode and the second gate electrode include a straight portion substantially straight in an edge of the first gate electrode and a straight portion substantially straight in an edge of the second gate electrode in plan view, and an end portion formed at a corner portion in which the edge of the first gate electrode is curved or bent and an end portion formed at a corner portion in which the edge of the second gate electrode (9) is curved or bent in plan view. A gate length of the first gate electrode at the end portion is set to be equal to or greater than a gate length of the first gate electrode at the straight portion.

Here, according to the invention, a portion in which the first gate electrode located between the source electrode and the drain electrode at the straight portion further extends and which surrounds the drain electrode at the end portion (that is, a portion not located between the source electrode and the drain electrode) is inclusively referred to as the first gate electrode. At the end portion, a length of the first gate electrode measured in a direction vertical to the edge of the first gate electrode on the drain electrode side in plan view is also referred to as a “gate length”.

In the field-effect transistor according to an embodiment, the first gate electrode and the second gate electrode include a straight portion substantially straight in an edge of the first gate electrode and a straight portion substantially straight in an edge of the second gate electrode in plan view, and an end portion formed at a corner portion in which the edge of the first gate electrode is curved or bent and an end portion formed at a corner portion in which the edge of the second gate electrode is curved or bent in plan view. A gate length of the second gate electrode at the end portion is set to be equal to or greater than a gate length of the second gate electrode at the straight portion.

Here, according to the invention, a portion in which the second gate electrode located between the first gate electrode and the source electrode at the straight portion further extends and which surrounds the source electrode at the end portion (that is, a portion not located between the first gate electrode and the source electrode) is inclusively referred to as the second gate electrode. At the end portion, a length of the second gate electrode measured in a direction vertical to the edge of the second gate electrode on the source electrode side in plan view is also referred to as a “gate length”.

### Advantageous Effects of Invention

As apparent from the above description, in the field-effect transistor according to the invention, the first gate electrode is disposed to surround the drain electrode in plan view.

Accordingly, in plan view, an electric field which is generated by the drain electrode and is at a high voltage can be received by the first gate electrode with a relatively high breakdown voltage including the end portions that are formed at corner portions in which the edge of the first gate electrode and the edge of the second gate electrode are curved or bent. In this way, the breakdown voltage can be ensured including the end portions.

Further, the second gate electrode is disposed to surround the source electrode in plan view.

Accordingly, a distance between the source electrode and the second gate electrode is prevented from being considerably lengthened at the end portion. Therefore, since influences of parasitic resistance and noise occurring between the source electrode and the second gate electrode can be reduced, a stable voltage between the source and the second gate including the end portions can be maintained. In this way, a stability operation can be performed. The end portions can also be completely depleted including the end portion, and thus carriers can be prevented from moving. Accordingly, current leakage transferring through the end portions can be reduced.

### BRIEF DESCRIPTION OF DRAWINGS

FIG. 1 is a plan view illustrating a field-effect transistor of the invention according to a first embodiment.

FIG. 2 is a perspective sectional view taken along the line A-A′ of FIG. 1.

FIG. 3 is a plan view according to a second embodiment.

FIG. 4 is a plan view according to a third embodiment.

FIG. 5 is a plan view according to a fourth embodiment.

FIG. 6 is a plan view according to a fifth embodiment.

FIG. 7 is a plan view according to a sixth embodiment.

FIG. 8 is a plan view according to a seventh embodiment.

FIG. 9 is a perspective sectional view taken along the line B-B′ of FIG. 8.

FIG. 10 is a plan view according to an eighth embodiment.

FIG. 11 is a perspective sectional view taken along the line C-C′ of FIG. 10.

FIG. 12 is a plan view according to a ninth embodiment.

### DESCRIPTION OF EMBODIMENTS

Hereinafter, the invention will be described in detail according to embodiments to be illustrated.

### First Embodiment

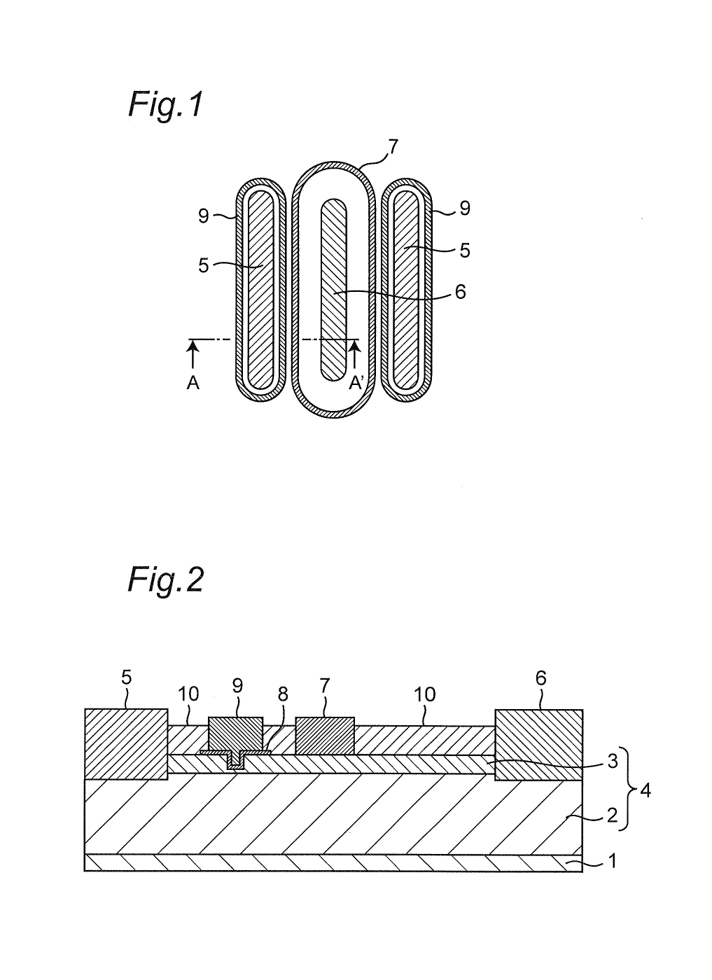

FIG. 1 is a plan view illustrating a nitride semiconductor HFET which is a field-effect transistor according to a first embodiment. FIG. 2 is a perspective sectional view taken along the line A-A′ of FIG. 1.

In the nitride semiconductor HFET, as illustrate in FIG. 2, a channel layer 2 formed of GaN and a barrier layer 3 formed of AlₓGa₁₋ₓN (where 0<x<1) are formed in this order on a substrate 1 formed of Si. Here, Al mixed ratio x of AlₓGa₁₋ₓN is, for example, x=0.17. Two-dimensional electron gas (2DEG) occurs on an interface between the channel layer 2 and the barrier layer 3. In the embodiment, a nitride semiconductor 4 is configured to include the channel layer 2 and the barrier layer 3. In the embodiment, the thickness of the barrier layer 3 is, for example, 30 nm.

A source electrode 5 and a drain electrode 6 are formed on the barrier layer 3 at a preset interval. In the embodiment, Ti/Al in which Ti and Al are laminated in this order is used as the source electrode 5 and the drain electrode 6. By forming recesses in spots in which the source electrode 5 and the drain electrode 6 are formed, depositing the electrode materials, and performing annealing, ohmic contacts are formed between the source electrode 5 and the 2DEG and between the drain electrode 6 and the 2DEG.

A first gate electrode 7 performing a normally-on (ON at a gate voltage of 0 V) operation is formed on the barrier layer 3 and between the source electrode 5 and the drain electrode 6, and Schottky junction is formed with the barrier layer 3.

In the embodiment, any material may be used as long as the first gate electrode 7 can function as a gate of a transistor. For example, a metal such as W, Ti, Ni, Al, Pt, or Au, a nitride such as WN or TiN, an alloy thereof, and a laminate structure thereof can be used. The first gate electrode 7 forms the Schottky junction with the nitride semiconductor 4. However, the invention is not limited thereto and a gate insulation film may be formed between the first gate electrode 7 and the nitride semiconductor 4.

A recess of the barrier layer 3 is formed on the barrier layer 3 and between the first gate electrode 7 and the source electrode 5, a gate insulation film 8 formed of a SiO₂ film is formed between the bottom surface and the side surface of the recess and on the barrier layer 3, and a second gate electrode 9 is formed on the gate insulation film 8. The second gate electrode 9 is formed to perform a normally-off (OFF at a gate voltage of 0 V) operation.

The structure in which the recess is formed in the second gate electrode 9 and the gate insulation film 8 is formed to realize the normally-off operation as in the embodiment is merely an example. Any structure may be used as long as the structure is a structure performing the normally-off operation. For example, SiO₂ is used as the gate insulation film 8, but any material may be allowed as long as the material has an insulation property, such as SiN or Al₂O₃. For example, a structure realizing the normally-off operation by forming a p-type semiconductor on the barrier layer 3 and raising a potential below the second gate electrode 9 may also be allowed.

An insulation film 10 formed of SiN is formed on the barrier layer 3 between the source electrode 5 and the second gate electrode 9, between the second gate electrode 9 and the first gate electrode 7, and between the first gate electrode 7 and the drain electrode 6. A function of the insulation film 10 is to suppress collapse (which is a phenomenon in which ON resistance is larger than in application of a voltage in a case in which an ON state is entered after application of the voltage to a drain at an OFF time) of the nitride semiconductor 4 while insulating electrodes from each other.

SiN used for the insulation film 10 is merely an example. Any material can be used as long as the material can electrically insulate electrodes from each other, as in SiO₂, Al₂O₃, and AIN.

Here, the gist of the embodiment will be described.

In the embodiment, a cascode connection structure is configured by forming the first gate electrode 7 performing the normally-on operation and the second gate electrode 9 performing the normally-off operation on the nitride semiconductor 4 and electrically connecting the first gate electrode 7 performing the normally-on operation to the source electrode 5 by a wiring (not illustrated). The second gate electrode 9 performing the normally-off operation using the nitride semiconductor 4 generally has a low breakdown voltage. However, by configuring the cascade connection in this way, the field-effect transistor with a high breakdown voltage can be configured by one chip and it is possible to reduce chip cost and reduce a package size.

In the structure of PTL 4, as illustrated in FIG. 1, both the edge of the first gate electrode and the edge of the second gate electrode are straight portions which are substantially straight and end portions which are curved or bent corner portions in plan view. That is, there are necessarily the end portions in plan view.

In recent years, for the HFET, it is desirable to enable a large current to flow at the time of an ON operation other than a high breakdown voltage. In a case in which a large current flows, it is general to widen a gate width. As a scheme, the above-described straight portion may be enlarged. Due to a restriction on a region, a scheme of disposing the plurality of structures of PTL 4 in parallel is used in conjunction with the enlarging of the straight portions.

The inventors have clarified that when the plurality of structures of PTL 4 are disposed in parallel, the numbers of end portions of the first gate electrodes and the second gate electrodes included in one chip are increased, and thus the many end portions cause an increase in current leakage and a breakdown voltage failure.

As the cause, influences of parasitic resistance and noise occur due to the structure of the drain electrode, the first gate electrode, the second gate electrode, and the source electrode at the end portions. Then, the influences of the parasitic resistance and the noise affect a stability operation of all the elements in some cases. Specifically, at the end portion, when an interval between the source electrode and the second gate electrode is excessively separated, the parasitic resistance, of course, occurs between the source electrode and the second gate electrode and therefore adversely affects a stability operation. As described above, in the technologies of the related art, countermeasures for the cross-sectional structure, that is, examination of the straight portion, are diversified. Examination of the end portion in plan view is small and clear solution schemes have not been mentioned.

As another problem, at the end portion, an electric field is easily concentrated from the shape of the end portion. Therefore, there is a problem that an increase in current leakage or a breakdown voltage failure occurs.

As a method of preventing a breakdown voltage failure and leakages transferring through the end portions, a method of causing the spots to enter an inactive state is considered. That is, at the above-described end portions, leakage is prevented by etching the barrier layer and working up the inactive state in which the 2DEG does not occur. There is also a method of not applying an electric field by not forming an electrode structure in a spot which is an inactive state. However, even when the inactive state is realized in the nitride semiconductor, the surface of the nitride semiconductor becomes a leakage source and unnegligible leakage occurs although the leakage is minuter than in an active region. Ultimately, it is considerably difficult to form a completely inactive spot. Therefore, the leakage may consequently occur between the electrodes in this method, which is not desirable.

Accordingly, according to the embodiment, as illustrated in FIG. 1, in plan view, the drain electrode 6 is completely surrounded by the first gate electrode 7 irrespective of the straight portions and the end portions and the source electrode 5 is completely surrounded by the second gate electrode 9 irrespective of the straight portions and the end portions.

In the embodiment, when the first gate electrode 7 completely surrounds the drain electrode 6 in plan view, an electric field which is generated by the drain electrode 6 and is at a high voltage can be received by the first gate electrode 7 with a relatively high breakdown voltage including the end portions. In this way, the breakdown voltage can be ensured including the end portions.

Simultaneously, a distance between the source and the second gate is considerably lengthened when the second gate electrode 9 completely surround the source electrode 5 irrespective of the straight portions and the end portions. Therefore, since the influences of the parasitic resistance and the noise can be reduced, a voltage between the source and the second gate including the end portions can be maintained, and therefore, a stability operation can be performed. The end portions can also be completely depleted and carriers can be prevented from moving, and thus current leakage transferring through the end portions is reduced.

### Second Embodiment

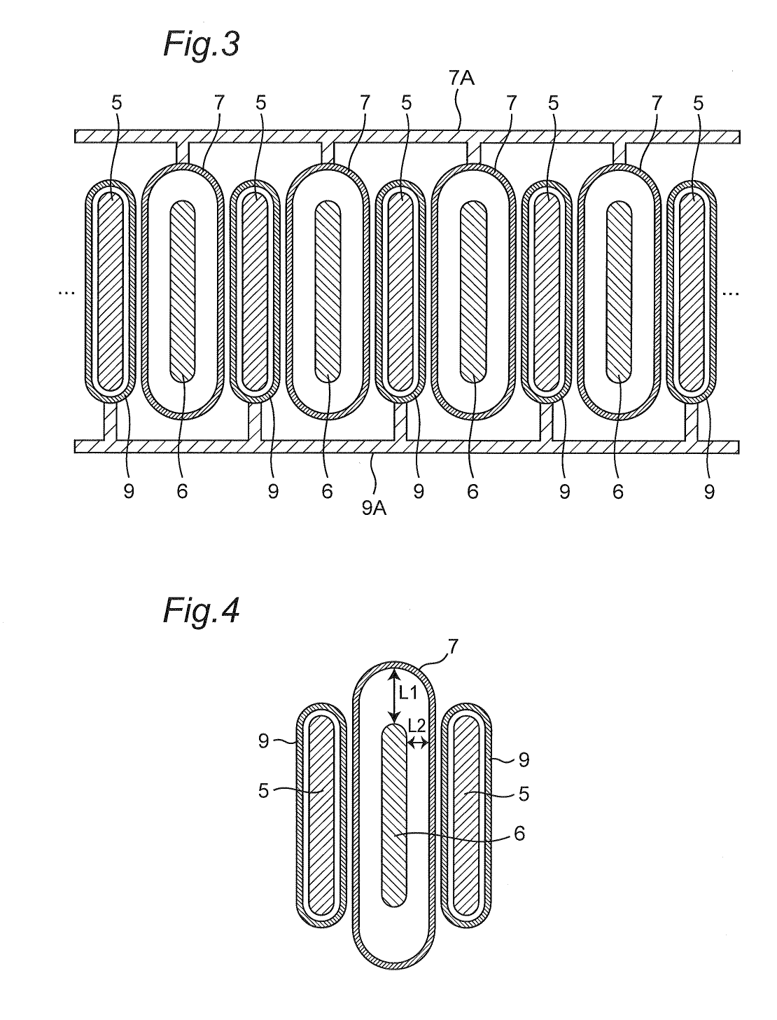

FIG. 3 is a plan view illustrating a nitride semiconductor HFET which is a field-effect transistor according to a second embodiment.

In the nitride semiconductor HFET, a cross-sectional surface in a direction orthogonal to the extension direction of the drain electrode 6 in FIG. 3 has substantially the same structure as that in FIG. 2 according to the first embodiment. Accordingly, the same reference numerals are given to the same members as those of the first embodiment and the detailed description thereof will be omitted. Hereinafter, differences from the first embodiment will be described.

In the embodiment, as illustrated in FIG. 3, the plurality of structures of the nitride semiconductor HFET illustrated in FIG. 1 according to the first embodiment are disposed in parallel in the direction orthogonal to the extension direction of the drain electrode 6 in plan view. A first gate electrode wiring 7A commonly connected to each first gate electrode 7 at one of the two end portions of the first gate electrode 7 in the individual nitride semiconductor HFET is formed and a second gate electrode wiring 9A commonly connected to each second gate electrode 9 at the other end of the two end portions of the second gate electrode 9 on the opposite side to the one end is formed. An element capable of allowing a large current to flow at the ON time is achieved when the element has this configuration.

At this time, the first gate electrode wiring 7A and the second gate electrode wiring 9A are drawn out without being intersected each other in plan view. This can be achieved since while the first gate electrode 7 surrounds the drain electrode 6 and the second gate electrode 9 surrounds the source electrode 5, the first gate electrode 7 and the second gate electrode 9 are not surrounded each other.

As described above, since the first gate electrode wiring 7A and the second gate electrode wiring 9A are not intersected each other in plan view, it is possible to considerably reduce capacitance between the source and the gate, and further it is possible to perform the stability operation.

### Third Embodiment

FIG. 4 is a plan view illustrating a nitride semiconductor HFET which is a field-effect transistor according to a third embodiment.

In the nitride semiconductor HFET, a cross-sectional surface in a direction orthogonal to the extension direction of the drain electrode 6 in FIG. 4 has substantially the same structure as that in FIG. 2 according to the first embodiment. Accordingly, the same reference numerals are given to the same members as those of the first embodiment and the detailed description thereof will be omitted. Hereinafter, differences from the first and second embodiments will be described.

In the embodiment, as illustrated in FIG. 4, in plan view, a distance L1 between the end portions of the first gate electrode 7 performing the normally-on operation and the drain electrode 6 is set to be the same as a distance L2 between the straight portions or longer than the distance L2.

At the end portion, an electric field is easily concentrated due to the shape of the end portion, current leakage increases more easily than in the straight portion. The end portion is also a spot which is easily broken down. Since a high voltage is applied between the drain electrode 6 and the first gate electrode 7, a high breakdown voltage is necessary.

Accordingly, in the embodiment, the distance between the first gate electrode 7 and the drain electrode 6 at the end portion is set to be longer than the distance at the straight portion in plan view, and thus a sufficient distance can be ensured. In this way, by alleviating the electric field at the end portions, it is possible to realize a reduction in new current leakage and an improvement in a breakdown voltage.

As illustrated in FIG. 4, it is desirable that a change in the distance between the first gate electrode 7 and the drain electrode 6 from the straight portions to the forefronts of the end portions be a continuous change. In this way, since a singular point such as a concave portion disappears, the concentration of the electric field rarely occurs, thereby realizing the structure in which breakdown rarely occurs.

### Fourth Embodiment

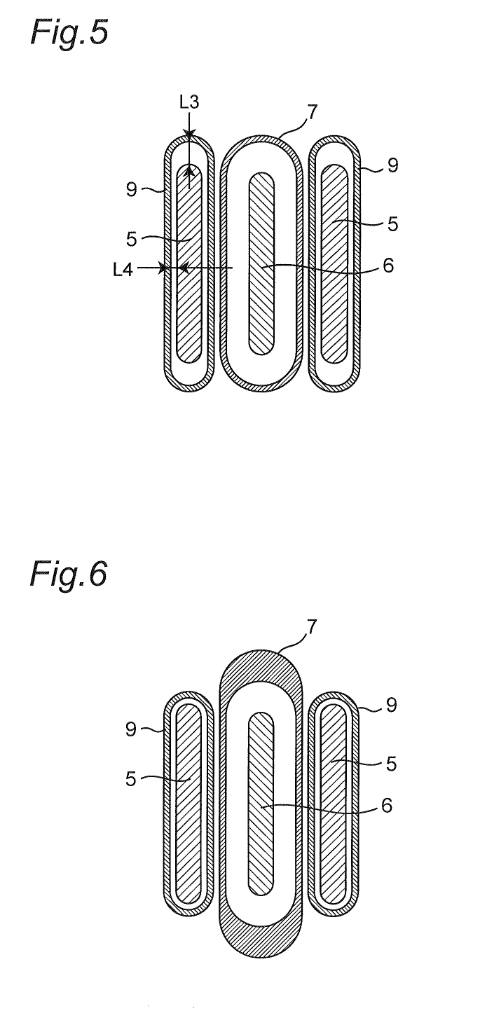

FIG. 5 is a plan view illustrating a nitride semiconductor HFET which is a field-effect transistor according to a fourth embodiment.

In the nitride semiconductor HFET, a cross-sectional surface in a direction orthogonal to the extension direction of the drain electrode 6 in FIG. 5 has substantially the same structure as that in FIG. 2 according to the first embodiment. Accordingly, the same reference numerals are given to the same members as those of the first embodiment and the detailed description thereof will be omitted. Hereinafter, differences from the first to third embodiments will be described.

In the embodiment, as illustrated in FIG. 5, in plan view, a distance L3 between the end portions of the second gate electrode 9 performing the normally-off operation and the source electrode 5 is set to be the same as a distance L4 between the straight portions or longer than the distance L4.

At the end portion, an electric field is easily concentrated due to the shape of the end portion, current leakage increases more easily than in the straight portion. The end portion is also a spot which is easily broken down. Since the second gate electrode 9 performing the normally-off operation generally has a low breakdown voltage, a structure in which the electric field is alleviated is necessary at the end portion at which the electric field is concentrated.

Accordingly, in the embodiment, the distance between the second gate electrode 9 and the source electrode 5 at the end portions is set to be longer than the distance at the straight portions in plan view, and thus a sufficient distance can be ensured. In this way, by alleviating the electric field at the end portions, it is possible to realize a reduction in new current leakage and an improvement in a breakdown voltage.

As illustrated in FIG. 5, it is desirable that a change in the distance between the second gate electrode 9 and the source electrode 5 from the straight portions to the forefronts of the end portions be a continuous change. In this way, since a singular point such as a concave portion disappears, the concentration of the electric field rarely occurs, thereby realizing the structure in which breakdown rarely occurs.

### Fifth Embodiment

FIG. 6 is a plan view illustrating a nitride semiconductor HFET which is a field-effect transistor according to a fifth embodiment.

In the nitride semiconductor HFET, a cross-sectional surface in a direction orthogonal to the extension direction of the drain electrode 6 in FIG. 6 has substantially the same structure as that in FIG. 2 according to the first embodiment. Accordingly, the same reference numerals are given to the same members as those of the first embodiment and the detailed description thereof will be omitted. Hereinafter, differences from the first to fourth embodiments will be described.

In the embodiment, as illustrated in FIG. 6, in plan view, a gate length of the first gate electrode 7 performing the normally-on operation at the end portion is set to be the same as a gate length at the straight portion or longer than the gate length at the straight portion.

At the end portion, an electric field is easily concentrated due to the shape of the end portion and a short channel effect easily occurs. When the short channel effect occurs, sub-threshold leakage flowing between the source electrode 5 and the drain electrode 6 may occur.

Accordingly, in the embodiment, the gate length of the first gate electrode 7 at the end portion is set to be equal to or sufficiently longer than the gate length at the straight portion in plan view. In this way, it is possible to prevent the short channel effect and realize a reduction in new current leakage and an improvement in a breakdown voltage.

As illustrated in FIG. 6, it is desirable that a change in the gate length of the first gate electrode 7 at the end portion from the straight portion side to the apex of the end portion be a continuous change. In this way, since a singular point such as a concave portion disappears, the concentration of the electric field rarely occurs, thereby realizing the structure in which breakdown rarely occurs.

### Sixth Embodiment

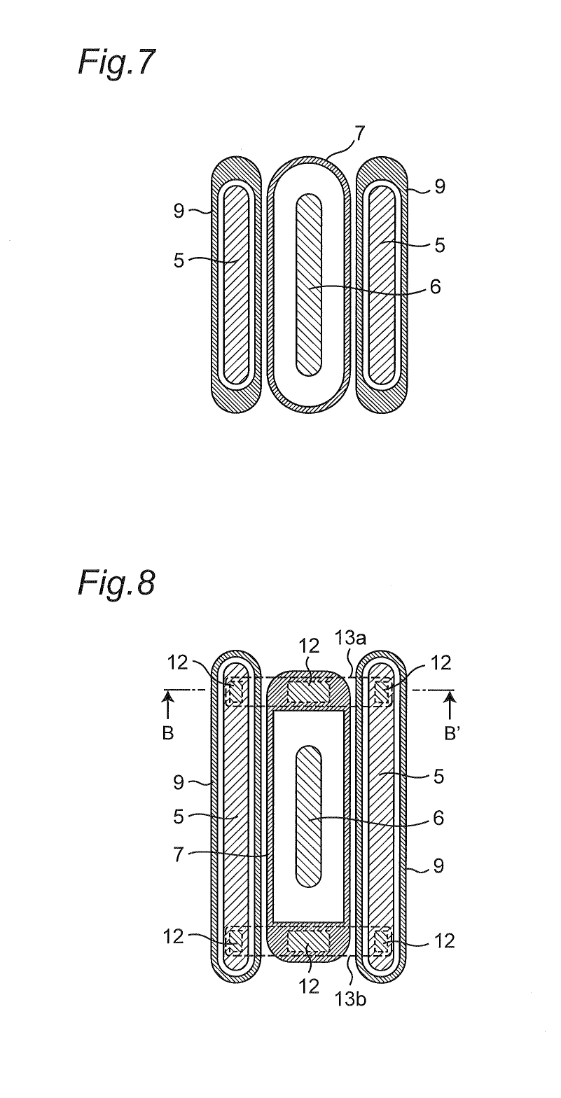

FIG. 7 is a plan view illustrating a nitride semiconductor HFET which is a field-effect transistor according to a sixth embodiment.

In the nitride semiconductor HFET, a cross-sectional surface in a direction orthogonal to the extension direction of the drain electrode 6 in FIG. 7 has substantially the same structure as that in FIG. 2 according to the first embodiment. Accordingly, the same reference numerals are given to the same members as those of the first embodiment and the detailed description thereof will be omitted. Hereinafter, differences from the first to fifth embodiments will be described.

In the embodiment, as illustrated in FIG. 7, in plan view, a gate length of the second gate electrode 9 performing the normally-off operation at the end portion is set to be the same as a gate length at the straight portion or longer than the gate length at the straight portion.

At the end portion, an electric field is easily concentrated due to the shape of the end portion and a short channel effect easily occurs. When the short channel effect occurs, sub-threshold leakage flowing between the source electrode 5 and the drain electrode 6 may occur.

Accordingly, in the embodiment, the gate length of the second gate electrode 9 at the end portion is set to be equal to or sufficiently longer than the gate length at the straight portion in plan view. In this way, it is possible to prevent the short channel effect and realize a reduction in new current leakage and an improvement in a breakdown voltage.

As illustrated in FIG. 7, it is desirable that a change in the gate length of the second gate electrode 9 at the end portion from the straight portion side to the apex of the end portion be a continuous change. In this way, since a singular point such as a concave portion disappears, the concentration of the electric field rarely occurs, thereby realizing the structure in which breakdown rarely occurs.

### Seventh Embodiment

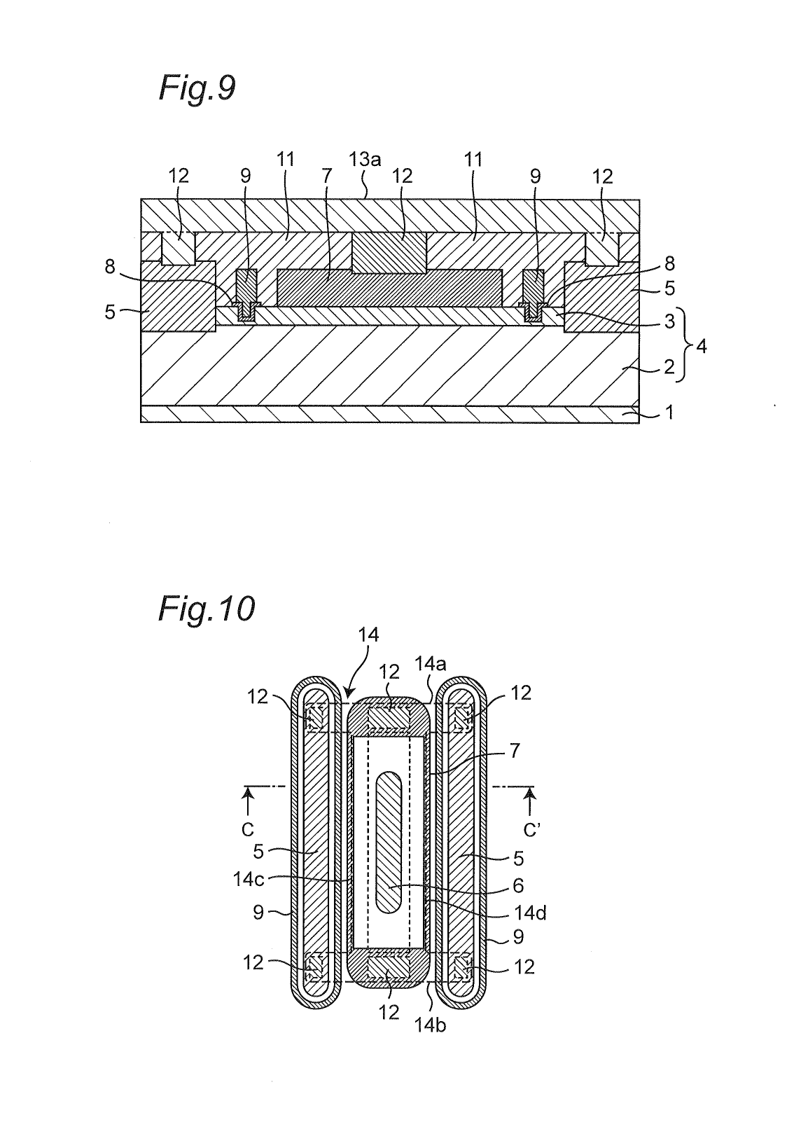

FIG. 8 is a plan view illustrating a nitride semiconductor HFET which is a field-effect transistor according to a seventh embodiment. FIG. 9 is a perspective sectional view taken along the line B-B′ of FIG. 8.

The substrate 1, the channel layer 2, the barrier layer 3, the nitride semiconductor 4, the source electrode 5, the drain electrode 6, the first gate electrode 7, the gate insulation film 8, and the second gate electrode 9 in the nitride semiconductor HFET have substantially the same structures of a case of the nitride semiconductor HFET according to the first embodiment. Accordingly, the same reference numerals are given to the same members as those of the first embodiment and the detailed description thereof will be omitted. Hereinafter, differences from the first to sixth embodiments will be described.

According to the seventh embodiment, an insulation film 11 formed of SiN is formed throughout the barrier layer 3, the source electrode 5, the drain electrode 6, the first gate electrode 7, and the second gate electrode 9. Accordingly, the insulation film 11 is also formed on the barrier layer 3 between the source electrode 5 and the second gate electrode 9, between the second gate electrode 9 and the first gate electrode 7, and between the first gate electrode 7 and the drain electrode 6.

As illustrated in FIGS. 8 and 9, at both the end portions of the first gate electrode 7, contact holes 12 are formed on the source electrode 5 and the first gate electrode 7 in the insulation film 11. Two conductive layers 13a and 13b are formed on the insulation film 11 from the contact hole 12 of the source electrode 5 to the contact hole 12 of the source electrode 5 on the opposite side through the contact hole 12 of the first gate electrode 7. In this way, the source electrode 5 and the first gate electrode 7 are electrically connected to each other via the contact holes 12 by the conductive layers 13a and 13b.

In this way, it is possible to considerably reduce parasitic inductance when the cascode connection is realized, and thus it is possible to perform a stability operation.

### Eighth Embodiment

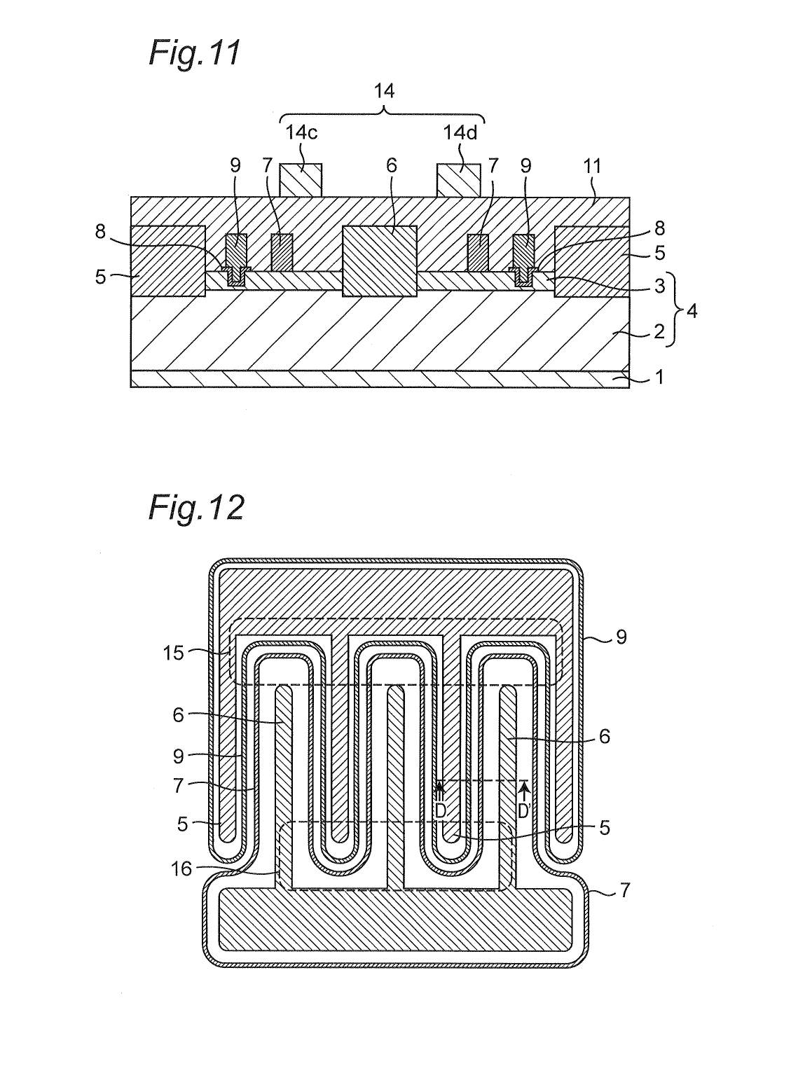

FIG. 10 is a plan view illustrating a nitride semiconductor HFET which is a field-effect transistor according to an eighth embodiment. FIG. 11 is a perspective sectional view taken along the line C-C′ of FIG. 10.

The substrate 1, the channel layer 2, the barrier layer 3, the nitride semiconductor 4, the source electrode 5, the drain electrode 6, the first gate electrode 7, the gate insulation film 8, and the second gate electrode 9 in the nitride semiconductor HFET have substantially the same structures of a case of the nitride semiconductor HFET according to the first embodiment. Accordingly, the same reference numerals are given to the same members as those of the first embodiment and the detailed description thereof will be omitted.

Further, the insulation film 11 and the contact holes 12 have substantially the same structures as the case of the nitride semiconductor HFET in the seventh embodiment. Accordingly, the same reference numerals are given to the same members as those of the seventh embodiment and the detailed description thereof will be omitted.

Hereinafter, differences from the first to seventh embodiments will be described.

According to the eighth embodiment, as illustrated in FIGS. 10 and 11, at both the end portions of the first gate electrode 7, two conductive layers 14a and 14b are formed on the insulation film 11 from the contact hole 12 of the source electrode 5 to the contact hole 12 of the source electrode 5 on the opposite side through the contact hole 12 of the first gate electrode 7. Further, two conductive layers 14c and 14d of which end portions are connected to the two conductive layers 14a and 14b and which are disposed between the two conductive layers 14a and 14b are formed. In this case, the conductive layers 14c and 14d are disposed on the two straight portions of the first gate electrode 7 and extend in an eave shape from the upper side of the first gate electrode 7 toward the side of the drain electrode 6.

In this way, the source electrode 5 and the first gate electrode 7 are electrically connected via the contact holes 12 by the conductive layer portion 14 in which the four conductive layers 14a, 14b, 14c, and 14d are combined with the shape of the Roman number “II”.

That is, according to the embodiment, in the straight portions, the conductive layer portions 14 do not exist on the second gate electrode 9. Therefore, it is possible to reduce parasitic capacitance between the source and the gate. In addition, it is possible to alleviate the concentration of an electric field on the first gate electrode 7 by the conductive layers 14c and 14d formed in the eave shape and it is possible to suppress the collapse and improve the breakdown voltage.

### Ninth Embodiment

FIG. 12 is a plan view illustrating a nitride semiconductor HFET which is a field-effect transistor according to a ninth embodiment. Here, a perspective cross-sectional surface taken along the like D-D′ in FIG. 12 has substantially the same structure as that in FIG. 2 according to the first embodiment.

The embodiment is a modification example of the first and third to sixth embodiments. The first and third to seventh embodiments are applied to a case in which the source electrode 5 and the drain electrode 6 have a shape of so-called comb-shaped electrode. That is, a structure in which the drain electrode 6 is surrounded by the first gate electrode 7 and the source electrode 5 is surrounded by the second gate electrode 9 is realized. In this case, reference numerals 15 and 16 denote the end portions.

FIG. 12 illustrates a basic structure in a case in which the first to sixth embodiments are applied. In practice, the structure is realized as follows.
In a case in which the first embodiment is applied, at the end portion 15, the drain electrode 6 is surrounded by the first gate electrode 7. On the other hand, at the end portion 16, the source electrode 5 is surrounded by the second gate electrode 9.
In a case in which the third embodiment is applied, the distance between the first gate electrode 7 and the drain electrode 6 at the end portion 15 is set to be equal to or greater than a distance at the straight portion.
In a case in which the fourth embodiment is applied, the distance between the second gate electrode 9 and the source electrode 5 at the end portion 16 is set to be equal to or greater than a distance at the straight portion.
In a case in which the fifth embodiment is applied, the gate length of the first gate electrode 7 at the end portion 15 is set to be longer than at the straight portion.
In a case in which the sixth embodiment is applied, the gate length of the second gate electrode 9 at the end portion 16 is set to be longer than at the straight portion.

Even in a case in which the source electrode 5 and the drain electrode 6 have the shape of a comb-shaped electrode, a field-effect transistor (nitride semiconductor HFET) in which leakage is reduced can be realized in the foregoing configuration.

In the second embodiment, the plurality of structures of the nitride semiconductor HFET according to the first embodiment are disposed in parallel. The first gate electrode 7 in the individual nitride semiconductor HFET is commonly connected to the first gate electrode wiring 7A. On the other hand, the second gate electrode 9 is commonly connected to the second gate electrode wiring 9A.

However, the invention is not limited thereto. The plurality of nitride semiconductors HFET described in any of the third to eighth embodiments may be disposed. The first gate electrode 7 in the individual nitride semiconductor HFET may be commonly connected to the first gate electrode wiring 7A. On the other hand, the second gate electrode 9 may be commonly connected to the second gate electrode wiring 9A. In a case in a case in which the invention is applied to the nitride semiconductor HFET described in the seventh and eighth embodiments, the first gate electrode wiring 7A may not be used.

In the third to eighth embodiments, the case in which the invention is applied to the nitride semiconductor HFET according to the first embodiment has been described as an example. The invention may be applied to any one of the third to eighth embodiments or a combination thereof.

In each of the embodiments, a Si substrate is used as the substrate 1 of the nitride semiconductor HFET. However, a sapphire substrate, a SiC substrate, or a GaN substrate may be used without being limited to the Si substrate.

Further, GaN is used as the channel layer 2 and AlₓGa₁₋ₓN is used as the barrier layer 3. However, the channel layer 2 and the barrier layer 3 are not limited to GaN and AlₓGa₁₋ₓN, but the nitride semiconductor 4 expressed with AlₓInyGa_{1-x-y}N (where x≧0, y≧0, and 0≧x+y<1) may be included. That is, the nitride semiconductor 4 may contain AlGaN, GaN, and InGaN or the like.

Further, a buffer layer may be appropriately formed in the nitride semiconductor 4 used in the invention. An AlN layer with a layer thickness of about 1 nm may be formed between the channel layer 2 and the barrier layer 3 in order to improve mobility. GaN may be formed as a cap layer on the barrier layer 3.

In each of the embodiments, by forming recesses in spots in which the source electrode 5 and the drain electrode 6 in the barrier layer 3 and the channel layer 2 are formed in the recess, depositing the electrode materials, and performing annealing, the ohmic contacts are formed between the source electrode 5 and the drain electrode 6, and the 2DEG. However, the method of forming the ohmic contacts is not limited thereto. For example, any forming method may be performed as long as the ohmic contacts can be formed between the electrodes 5 and 6, and the 2DEG. For example, a contact undoped AlGaN layer is formed with a thickness of, for example, 15 nm on the channel layer 2. Then, the ohmic contacts may be formed by directly depositing an electrode material on the undoped AlGaN layer without forming recesses, forming the source electrode 5 and the drain electrode 6, and performing annealing.

In each of the embodiments, the source electrode 5 and the drain electrode 6 are used using Ti/Al in which Ti and Al are laminated in this order. However, the invention is not limited thereto. Any material may be used as long as the material has an electrical conduction property and ohmic contact with the 2DEG is possible. For example, Ti/Al/TiN in which Ti, Al, and TiN are laminated in this order may be used. In addition, AlSi, AlCu, and Au may be used instead of the foregoing Al or may be laminated on the foregoing Al.

The dimensions of the portions and the film thicknesses in the embodiment are merely examples and are within an application range of the invention in the structure according to the invention.

In summary, a field-effect transistor according to the invention includes: a nitride semiconductor layer 4 that includes a heterojunction; a source electrode 5 and a drain electrode 6 that are disposed on the nitride semiconductor layer 4 at an interval; a first gate electrode 7 that is located between the source electrode 5 and the drain electrode 6 and performs a normally-on operation; and a second gate electrode 9 that is located between the first gate electrode 7 and the source electrode 5 and perform a normally-off operation. The first gate electrode 7 is disposed to surround the drain electrode 6 in plan view. The second gate electrode 9 is disposed to surround the source electrode 5 in plan view.

In the configuration, the first gate electrode 7 is disposed to surround the drain electrode 6 in plan view.

Accordingly, when the first gate electrode 7 completely surrounds the drain electrode 6 in plan view, an electric field which is generated by the drain electrode 6 and is at a high voltage can be received by the first gate electrode 7 with a relatively high breakdown voltage including the end portions that are formed at corner portions in which the edge of the first gate electrode 7 and the edge of the second gate electrode 9 are curved or bent. In this way, the breakdown voltage can be ensured including the end portions.

In the configuration, the second gate electrode 9 is disposed to surround the source electrode 5 in plan view.

Accordingly, a distance between the source electrode 5 and the second gate electrode 9 is prevented from being considerably lengthened at the end portion. Therefore, since influences of parasitic resistance and noise occurring between the source electrode 5 and the second gate electrode 9 can be reduced, a stable voltage between the source and the second gate including the end portions can be maintained. In this way, a stability operation can be performed. The end portions can also be completely depleted including the end portion, and thus carriers can be prevented from moving. Accordingly, current leakage transferring through the end portions can be reduced.

According to an embodiment, in the field-effect transistor, the first gate electrode 7 and the second gate electrode 9 each include a straight portion that is substantially straight in one of an edge of the first gate electrode 7 and an edge of the second gate electrode 9 in plan view and an end portion that is formed at a corner portion in which the edge of the first gate electrode 7 and the edge of the second gate electrode 9 is curved or bent in plan view, and an interval between the first gate electrode 7 and the drain electrode 6 at the end portion is set to be equal to or greater than an interval between the first gate electrode 7 and the drain electrode 6 at the straight portion.

At the end portion, an electric field is easily concentrated due to the shape of the end portion, current leakage increases more easily than in the straight portion. The end portion is also a spot which is easily broken down. A high voltage is applied between the drain electrode 6 and the first gate electrode 7, and thus a high breakdown voltage is necessary.

According to the embodiment, the interval between the first gate electrode 7 and the drain electrode 6 at the end portion is set to be equal to or greater than the interval between the first gate electrode 7 and the drain electrode 6 at the straight portions. In this way, by alleviating the electric field at the end portions, it is possible to realize a reduction in new current leakage and an improvement in a breakdown voltage.

According to an embodiment, in the field-effect transistor, the first gate electrode 7 and the second gate electrode 9 each include a straight portion that is substantially straight in one of an edge of the first gate electrode 7 and an edge of the second gate electrode 9 in plan view and an end portion that is formed at a corner portion in which the edge of the first gate electrode 7 and the edge of the second gate electrode 9 is curved or bent in plan view. An interval between the second gate electrode 9 and the source electrode 5 at the end portion is set to be equal to or greater than an interval between the second gate electrode 9 and the source electrode 5 at the straight portion.

At the end portion, an electric field is easily concentrated due to the shape of the end portion, current leakage increases more easily than in the straight portion. The end portion is also a spot which is easily broken down. Since a breakdown voltage is generally low in the second gate electrode 9 performing the normally-off operation, a structure in which the concentration of the electric field is alleviated at the end portion at which the electric field is concentrated is necessary.

According to the embodiment, the interval between the second gate electrode 9 and the source electrode 5 at the end portion is set to be equal to or greater than the interval between the second gate electrode 9 and the source electrode 5 at the straight portions. In this way, by alleviating the electric field at the end portions, it is possible to realize a reduction in new current leakage and an improvement in a breakdown voltage.

According to an embodiment, in the field-effect transistor, the first gate electrode 7 and the second gate electrode 9 each include a straight portion that is substantially straight in one of an edge of the first gate electrode 7 and an edge of the second gate electrode 9 in plan view and an end portion that is formed at a corner portion in which the edge of the first gate electrode 7 and the edge of the second gate electrode 9 is curved or bent in plan view. A gate length of the first gate electrode 7 at the end portion is set to be equal to or greater than a gate length of the first gate electrode 7 at the straight portion.

At the end portion, an electric field is easily concentrated due to the shape of the end portion and a short channel effect easily occurs. When the short channel effect occurs, sub-threshold leakage flowing between the source electrode 5 and the drain electrode 6 may occur.

According to the embodiment, the gate length of the first gate electrode 7 at the end portion is set to be equal to or sufficiently longer than the gate length of the first gate electrode 7 at the straight portion. In this way, it is possible to prevent the short channel effect and realize a reduction in new current leakage and an improvement in a breakdown voltage.

According to an embodiment, in the field-effect transistor, the first gate electrode 7 and the second gate electrode 9 each include a straight portion that is substantially straight in one of an edge of the first gate electrode 7 and an edge of the second gate electrode 9 in plan view and an end portion that is formed at a corner portion in which the edge of the first gate electrode 7 and the edge of the second gate electrode 9 is curved or bent in plan view. A gate length of the second gate electrode 9 at the end portion is set to be equal to or greater than a gate length of the second gate electrode 9 at the straight portion.

According to the embodiment, the gate length of the second gate electrode 9 at the end portion is set to be equal to or longer than the gate length of the second gate electrode 9 at the straight portion. In this way, it is possible to prevent the short channel effect easily occurring at the end portion and realize a reduction in new current leakage and an improvement in a breakdown voltage.

In the field-effect transistor according to an embodiment, in regard to the straight portion side to the apex at the end portion, a change in the interval between the first gate electrode 7 and the drain electrode 6, a change in the interval between the second gate electrode 9 and the source electrode 5, a change in the gate length of the first gate electrode 7, or a change in the gate length of the second gate electrode 9 is a continuous change.

According to the embodiment, in regard to the straight portion side to the apex at the end portion, a change in the interval between the first gate electrode 7 and the drain electrode 6, a change in the interval between the second gate electrode 9 and the source electrode 5, a change in the gate length of the first gate electrode 7, or a change in the gate length of the second gate electrode 9 is a continuous change. Accordingly, since a singular point such as a concave portion caused due to the change disappears, the concentration of the electric field rarely occurs, thereby realizing the structure in which breakdown rarely occurs.

### REFERENCE SIGNS LIST

1 SUBSTRATE
2 CHANNEL LAYER
3 BARRIER LAYER
4 NITRIDE SEMICONDUCTOR
5 SOURCE ELECTRODE
6 DRAIN ELECTRODE
7 FIRST GATE ELECTRODE
7A FIRST GATE ELECTRODE WIRING
8 GATE INSULATION FILM
9 SECOND GATE ELECTRODE
9A SECOND GATE ELECTRODE WIRING
10, 11 INSULATION FILM
12 CONTACT HOLE
13a, 13b, 14a, 14b, 14c, 14d CONDUCTIVE LAYER
14 CONDUCTIVE LAYER PORTION
15, 16 END PORTION

1. (canceled)

2. (canceled)

3. (canceled)

4. (canceled)

5. (canceled)

6. A field-effect transistor comprising:
a nitride semiconductor layer that includes a heterojunction;
a source electrode and a drain electrode that are disposed on the nitride semiconductor layer at an interval;
a first gate electrode that is located between the source electrode and the drain electrode and performs a normally-on operation; and
a second gate electrode that is located between the first gate electrode and the source electrode and performs a normally-off operation,
wherein the first gate electrode is disposed to surround the drain electrode in plan view,
wherein the second gate electrode is disposed to surround the source electrode in plan view,
wherein the first gate electrode and the second gate electrode include a straight portion substantially straight in an edge of the first gate electrode and a straight portion substantially straight in an edge of the second gate electrode in plan view, and an end portion formed at a corner portion in which the edge of the first gate electrode is curved or bent and an end portion formed at a corner portion in which the edge of the second gate electrode is curved or bent in plan view, and
wherein a gate length of the first gate electrode at the end portion is set to be equal to or greater than a gate length of the first gate electrode at the straight portion.

7. The field-effect transistor according to claim 6,
wherein a gate length of the second gate electrode at the end portion is set to be equal to or greater than a gate length of the second gate electrode at the straight portion.

8. The field-effect transistor according to claim 6,
wherein an interval between the first gate electrode and the drain electrode at the end portion is set to be equal to or greater than an interval between the first gate electrode and the drain electrode at the straight portion.

9. The field-effect transistor according to claim 7,
wherein an interval between the first gate electrode and the drain electrode at the end portion is set to be equal to or greater than an interval between the first gate electrode and the drain electrode at the straight portion.

10. The field-effect transistor according to claim 6,
wherein an interval between the second gate electrode and the source electrode at the end portion is set to be equal to or greater than an interval between the second gate electrode and the source electrode at the straight portion.

11. The field-effect transistor according to claim 7,
wherein an interval between the second gate electrode and the source electrode at the end portion is set to be equal to or greater than an interval between the second gate electrode and the source electrode at the straight portion.

12. A field-effect transistor comprising:
a nitride semiconductor layer that includes a heterojunction;
a source electrode and a drain electrode that are disposed on the nitride semiconductor layer at an interval;
a first gate electrode that is located between the source electrode and the drain electrode and performs a normally-on operation; and
a second gate electrode that is located between the first gate electrode and the source electrode and performs a normally-off operation,
wherein the first gate electrode is disposed to surround the drain electrode in plan view,
wherein the second gate electrode is disposed to surround the source electrode in plan view,
wherein the first gate electrode and the second gate electrode include a straight portion substantially straight in an edge of the first gate electrode and a straight portion substantially straight in an edge of the second gate electrode in plan view, and an end portion formed at a corner portion in which the edge of the first gate electrode is curved or bent and an end portion formed at a corner portion in which the edge of the second gate electrode is curved or bent in plan view, and
wherein a gate length of the second gate electrode at the end portion is set to be equal to or greater than a gate length of the second gate electrode at the straight portion.

13. The field-effect transistor according to claim 12,
wherein an interval between the first gate electrode and the drain electrode at the end portion is set to be equal to or greater than an interval between the first gate electrode and the drain electrode at the straight portion.

14. The field-effect transistor according to claim 12,
wherein an interval between the second gate electrode and the source electrode at the end portion is set to be equal to or greater than an interval between the second gate electrode and the source electrode at the straight portion.

15. The field-effect transistor according to claim 13,
wherein an interval between the second gate electrode and the source electrode at the end portion is set to be equal to or greater than an interval between the second gate electrode and the source electrode at the straight portion.
